(19) United States
(12) Patent Application Publication
(10) Pub. No.: US 2026/0096452 A1
(43) Pub. Date: Apr. 2, 2026

(54) COMMUNICATION INTERFACE WITH IMPROVED RELIABILITY OR THROUGHPUT

(71) Applicant: QUALCOMM Incorporated, San Diego, CA (US)

(72) Inventors: Sang TRAN, Encinitas, CA (US); Rongtian ZHANG, San Diego, CA (US); Santhosh Reddy AKAVARAM, Hyderabad (IN)

(21) Appl. No.: 18/899,624

(22) Filed: Sep. 27, 2024

(51) Int. Cl. H01L 23/538; H01L 25/065; H04J 3/06

(52) U.S. Cl. CPC H10W 70/60; H04J 3/0638; H10W 70/611; H10W 90/00

(57) ABSTRACT

Certain aspects of the present disclosure are directed towards an apparatus or techniques for data communication. One example apparatus generally includes: a main band (MB) communication interface comprising at least one first data line coupled between a first electronic component and a second electronic component and configured to perform MB data communication via the at least one first data line; a side band (SB) communication interface comprising at least one second data line coupled between the first electronic component and the second electronic component; and a first processing component configured to provide data for communication via the at least one second data line of the SB communication interface, wherein to provide the data, the first processing component is configured to select one of SB data and first MB data associated with the MB communication interface.

### TECHNICAL FIELD

Certain aspects of the present disclosure generally relate to electronic circuits and, more particularly, to techniques for data communication between electronic components.

### BACKGROUND

Universal Chiplet Interconnect Express (UCIe) is a standard designed to facilitate data communications between chiplets. A chiplet generally refers to a small modular chip that is designed to perform a specific function. UCIe is developed to address the growing complexity and demand for flexibility in semiconductor design. UCIe provides a high-speed, scalable, and efficient interconnect between chiplets. UCIe provides a standardized communication interface, making the design of advanced systems more streamlined and efficient. UCIe may be implemented with a mainband (MB) interface and a sideband (SB) interface, where the MB interface is typically used for data communications and the SB interface is used for parameter exchanges, register accesses for debugging/compliance and coordination for link training and management.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure are directed towards an apparatus for data communication. The apparatus generally includes: a main band (MB) communication interface comprising at least one first data line coupled between a first electronic component and a second electronic component and configured to perform MB data communication via the at least one first data line; a side band (SB) communication interface comprising at least one second data line coupled between the first electronic component and the second electronic component; and a first processing component configured to provide data for communication via the at least one second data line of the SB communication interface, wherein to provide the data, the first processing component is configured to select one of SB data and first MB data associated with the MB communication interface.

Certain aspects of the present disclosure are directed towards a method for data communication. The method generally includes: performing MB data communication via at least one first data line of a main band (MB) communication interface coupled between a first electronic component and a second electronic component; selecting one of SB data and first MB data associated with the MB communication interface; and providing data for communication via at least one second data line of an SB communication interface coupled between the first electronic component and the second electronic component based on the selection.

Certain aspects of the present disclosure are directed towards a multi-chiplet package. The multi-chiplet package generally includes: a first chiplet; a second chiplet; a main band (MB) communication interface comprising at least one first data line coupled between the first chiplet and the second chiplet and configured to perform MB data communication via the at least one first data line; a side band (SB) communication interface comprising at least one second data line coupled between the first chiplet and the second chiplet; and a processing component configured to provide data for communication via the at least one second data line of the SB communication interface, wherein to provide the data, the processing component is configured to select one of SB data and MB data associated with the MB communication interface.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a block diagram of an example device, in which aspects of the present disclosure may be practiced.

FIG. 2 is a block diagram of a multi-chiplet package implemented with communication circuitry, in accordance with certain aspects of the present disclosure.

FIG. 3 illustrates an electronic device implemented with a four-module configuration of a communication interface, in accordance with certain aspects of the present disclosure.

FIG. 4 illustrates sideband (SB) circuitry for generating signals for communication on an SB interface, in accordance with certain aspects of the present disclosure.

FIG. 5 illustrates example operations for data communication, in accordance with certain of the present disclosure.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Certain aspects of the present disclosure are directed towards techniques for improving the reliability or throughput of a communication interface. For example, as described in more detail herein, a communication interface may be implemented with a side band (SB) interface and a main band (MB) interface, where the MB is used to communicate data between components and the SB is used to communicate control information between the components. In some aspects of the present disclosure, the SB interface may be used to communicate parity or error correction code (ECC) data corresponding to MB data, or a copy of the MB data for redundancy, to increase reliability. In some aspects, the SB interface may be used to communicate data in addition to any data communicated via the MB interface to increase throughput. As used herein, an MB interface generally refers to an interface that may be used for data communications and an SB interface generally refers to an interface that may be used for communication of control information. In some aspects, the SB interface may also be used for data communications as described in more detail herein.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

It should be understood that aspects of the present disclosure may be used in a variety of applications. Although the present disclosure is not limited in this respect, the circuits disclosed herein may be used in any of various suitable apparatuses, such as in the power supply, battery charging circuit, or power management circuit of a communication system, a video codec, audio equipment such as music players and microphones, a television, camera equipment, and test equipment such as an oscilloscope. Communication systems intended to be included within the scope of the present disclosure include, by way of example only, cellular radiotelephone communication systems, satellite communication systems, two-way radio communication systems, one-way pagers, two-way pagers, personal communication systems (PCS), personal digital assistants (PDAs), and the like.

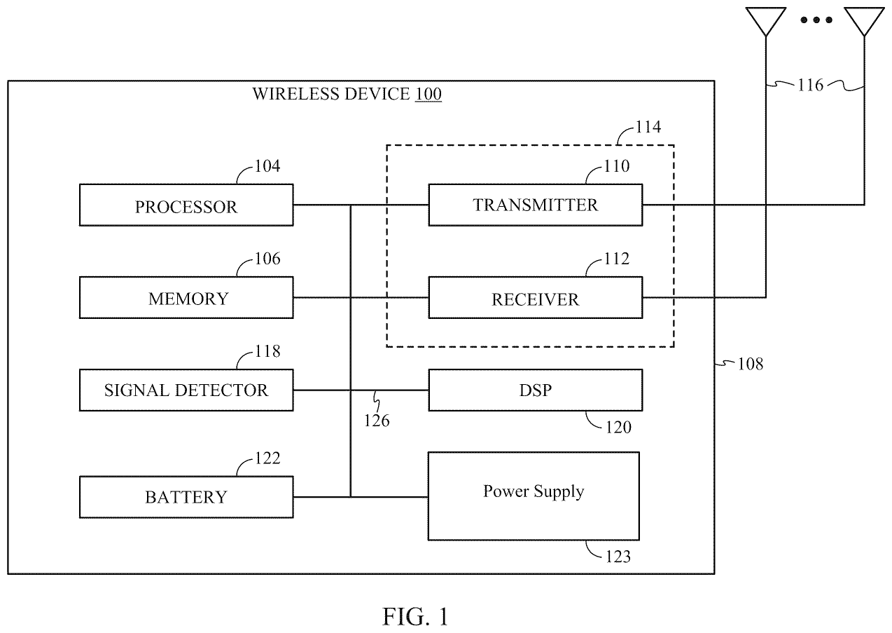

FIG. 1 illustrates an example device 100 in which aspects of the present disclosure may be implemented. The device 100 may be a battery-operated device such as a cellular phone, a PDA, a handheld device, a wireless device, a laptop computer, a tablet, a smartphone, an Internet of things (IoT) device, a wearable device, a virtual reality (VR) or augmented reality (AR) device, etc.

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106.

In certain aspects, the device 100 may also include a housing 108 that may include a transmitter 110 and a receiver 112 to allow transmission and reception of data between the device 100 and a remote location. For certain aspects, the transmitter 110 and receiver 112 may be combined into a transceiver 114. One or more antennas 116 may be attached or otherwise coupled to the housing 108 and electrically connected to the transceiver 114. The device 100 may also include (not shown) multiple transmitters, multiple receivers, and/or multiple transceivers.

The device 100 may also include a signal detector 118 that may be used in an effort to detect and quantify the level of signals received by the transceiver 114. The signal detector 118 may detect such signal parameters as total energy, energy per subcarrier per symbol, and power spectral density, among others. The device 100 may also include a digital signal processor (DSP) 120 for use in processing signals.

The device 100 may further include a battery 122, which may be used to power the various components of the device 100 (e.g., when the device is disconnected from an external power source). The device 100 may also include a power supply system 123 for managing the power from the battery (or from one or more power ports for receiving external power) to the various components of the device 100. At least a portion of the power supply system 123 may be implemented in one or more power management integrated circuits (power management ICs or PMICs) The power supply system 123 may perform a variety of functions for the device 100 such as DC-to-DC conversion, battery charging, power-source selection, voltage scaling, power sequencing, etc. In some aspects, the device 100 may be implemented using a multi-chiplet package with a communication interface for data communications between chiplets, as described in more detail herein.

The various components of the device 100 may be coupled together by a bus system 126, which may include a power bus, a control signal bus, and/or a status signal bus in addition to a data bus. Additionally or alternatively, various combinations of the components of the device 100 may be coupled together by one or more other suitable techniques.

### Example Techniques for Data Communications

Certain aspects of the present disclosure are directed towards an apparatus and techniques for fast and reliable data transfer between electronic devices, such as chiplets. Auto and compute platforms involve fast, secure, and reliable communication between chiplets. Periodical error checks/diagnosis may be performed often to improve reliability. A chiplet is a small integrated circuit. While some examples provided herein are described with respect to chiplets and communications using universal chiplet interconnect express (UCIe) standard, certain aspects of the present disclosure may be implemented for data communications between any electronic components and using any suitable communication interface.

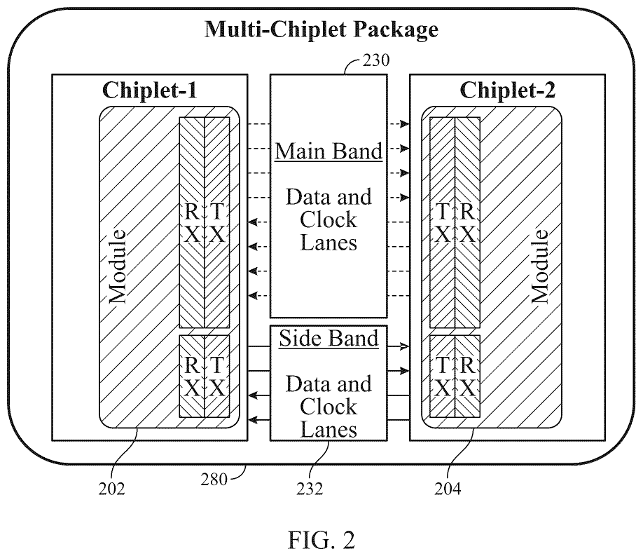

FIG. 2 is a block diagram of communication circuitry (e.g., implemented using a universal chiplet interconnect express (UCIe)) used to provide data communications between chiplets of a multi-chiplet package 280 (labeled “Chiplet-1” and “Chiplet-2”). The multi-die package 280 may include a main band (MB) interface 230 with data lines (e.g., 16 or 64 data lanes in each direction between the dies) for communicating MB data between Chiplet-1 and Chiplet-2. As used herein, MB data refers to data that may be communicated via the MB interface 230 that is separate from control information that may be communicated on a separate interface (e.g., a side band (SB) interface). Chiplet-1 may include communication circuitry 202 (e.g., also referred to as a “module”) including transmit (TX) and receive (RX) circuits and Chiplet-2 may include communication circuitry 204 (e.g., also referred to as a “module”) including MB TX and RX circuits, where the communication circuitry 202, 204 are used for the communication of MB data via the MB interface between Chiplet-1 and Chiplet-2. The MB interface 230 may also include clock lines (e.g., two clock lanes in each direction between the dies) for communicating clock signals between Chiplet-1 and Chiplet-2. While data and clock lanes of the MB interface 230 are described, the MB interface 230 may also include other lanes for data transfer management. The MB interface 230 may be used to provide a data path between Chiplet-1 and Chiplet-2 and may provide high-speed data transfer (e.g., 4, 8, 12, 16, 24, 32 Giga transfers per second (GT/s)).

The multi-chiplet package 280 may also include an SB interface 232 that may include data and clock lanes. The communication circuitry 202 may also include SB TX and RX circuits for communication via the SB interface 232. The SB interface 232 may be used to communicate control information and information for the initialization of the UCIe. For example, the SB interface may be used for parameter exchanges, register accesses for debugging/compliance and coordination for link training and management, which may be generally referred to herein as control information. The SB interface 232 may have a slower transfer rate (e.g., 800 mega transfers per second (MT/s)) than the MB interface 230. The MB and SB interfaces may operate asynchronously using respective data lanes and clock lanes. While two modules are shown in FIG. 2, the communication techniques described herein may be used for communications between any suitable number of modules. For example, UCIe may be used for a two-module or a four-module configuration.

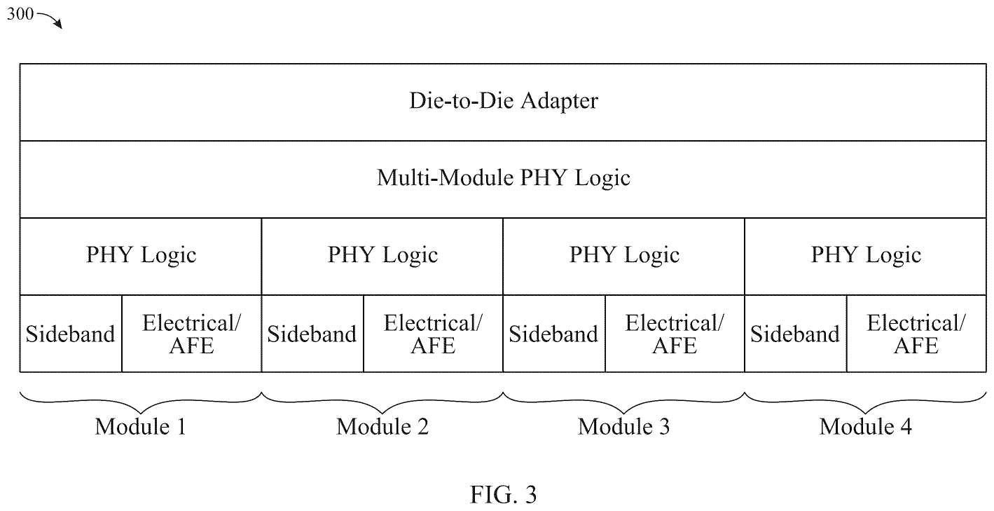

FIG. 3 illustrates an electronic device 300 implemented with a four-module configuration of UCIe. The electronic device 300 may be implemented with UCIe to communicate with another electronic device not shown in FIG. 3. As shown, electronic device 300 may include a chiplet-to-chiplet adaptor to coordinate the data transfer across the UCIe link. The device 300 may also include a multi-module physical layer (PHY) logic and PHY logic for each module (e.g., modules 1-4) which may include SB components (e.g., SB TX and RX circuits) and MB components (e.g., MB RX and TX circuits) implemented using electrical and analog front end (AFE). Each module in a multi-module configuration may perform initialization and training operations independently using respective SB interfaces. The electronic device 300 may send SB messages (e.g., control signals) on the SB interface of the numerically least module identifier (ID) having an active link training state machine (LTSM). For example, module 1 may have the numerically least module ID and have an LTSM that is active and may be used for communicating SB messages, where the SB interfaces for the other modules (modules 2-3) are inactive. In other words, the SB interfaces for modules 2-3 may be in an idle state, and the SB interface for module 1 may be used from time to time to send control messages.

Certain aspects of the present disclosure use the SB interface of one or more modules to increase the data throughput or data reliability of the communication circuitry (e.g., UCIe), increasing the utilization of the SB bandwidth. For example, in some aspects, the SB interface may transfer metadata (e.g., parity or error correction code (ECC) data) for MB data, while the MB interface transfers the MB data, increasing data reliability. The metadata may be redundant data from the MB or parity/ECC data. In some aspects, the SB interface may be used to transfer MB data to increase throughput.

In some aspects, the communication circuitry (e.g., UCIe) may be operated in synchronized mode (also referred to as “sync mode”). During sync mode, an SB clock signal communicated via the SB interface and an MB clock communicated via the MB interface may be synchronized. In sync mode, the SB clock signal may be programmable to operate at a frequency that is a fraction of the frequency of the MB clock signal. As a result, the data rate of the SB interface may be at a fraction of the data rate of the MB interface. The frequency of the SB clock may be adjusted based on a tradeoff between data throughput and reliability. That is, a lower SB clock frequency may be used to increase the reliability of data communicated via the SB interface or a higher SB clock frequency may be used to increase throughput. Furthermore, the SB may be programmable to allocate a portion of time for communicating metadata and another portion of time for communicating SB messages (e.g., for regular administrative control and maintenance operations). In this manner, the SB may continue to support the communication of control information at specific periods and be used to increase reliability or throughput when the SB would otherwise be idle.

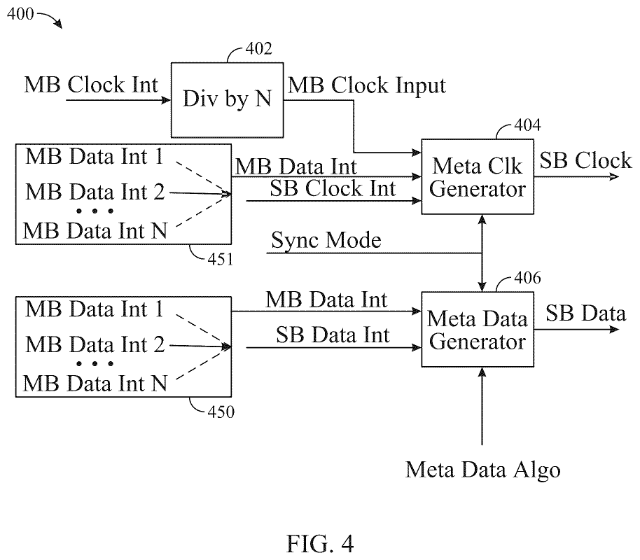

FIG. 4 illustrates SB circuitry 400 for generating signals for communication on an SB interface, in accordance with certain aspects of the present disclosure. The SB circuitry 400 may be part of the SB TX circuit of the communication interface 202. As shown, the SB circuitry 400 may include a meta clock generator 404 (e.g., also referred to herein as a “processing component”) for generating a signal (e.g., clock signal or data) for communicating on a clock line of the SB interface. As used herein, a clock line refers to a line of an interface used to communicate a clock signal, although in some aspects of the present disclosure, the clock line may be used to communicate data to increase throughput or reliability. The SB circuitry 400 may include a metadata generator 406 for generating SB data, which may be either parity/ECC data or redundant MB data to increase reliability, or data from the MB to increase throughput. The circuitry 400 may also include a frequency divider 402 configured to divide the frequency of an internal MB clock (labeled “MB Clock Int”) by a positive integer N to generate an MB clock input signal to the generator 404. For example, the MB clock input signal may be the same as the internal MB clock if N is equal to 1 or a frequency-divided version of the internal MB clock if N is greater than 1. The MB clock input signal may be synchronized with the internal MB clock.

In some aspects, generators 404, 406 may receive a sync mode select signal (labeled “sync mode”), as shown. If the sync mode select signal indicates to operate in sync mode, the generator 404 selects the MB clock input signal from the divider circuit 402 that is synchronized with the internal MB clock and provides the MB clock input signal for communication via the SB clock lane. Otherwise, if the sync mode select signal indicates to operate in non-sync mode (e.g., unsynchronized mode), the generator 404 selects the internal SB clock signal (labeled “SB Clock Int”) and provides the internal SB clock signal for communication via the SB clock lane. The internal SB clock signal may be unsynchronized with the internal MB clock signal.

In some aspects, the generator 406 may receive internal SB data (labeled “SB Data Int”) and internal MB data (labeled “MB Data Int”). If the sync mode select signal indicates to operate in non-sync mode (e.g., unsynchronized mode), the generator 406 selects the internal SB data and provides the internal SB data for communication via the SB data lane. If the sync mode select signal indicates to operate in sync mode, the generator 406 selects the internal MB data and provides the internal MB data (or a processed version thereof) for communication via the SB data lane. For example, the internal MB data may be processed using a metadata algorithm to generate processed data to be communicated via the SB data lane. For instance, the processed data may be parity/ECC data associated with the internal MB data. The data provided for communication via the SB data lane may be the internal MB data (e.g., without further processing) to provide data redundancy for increased reliability or data throughput. For instance, the internal MB data may also be communicated via the MB interface. Thus, the internal MB data may also be communicated via the SB interface to provide data redundancy and increase reliability. On the other hand, the internal MB data may be data sent on the SB interface that is in addition to any data sent via the MB interface, providing increased throughput.

As described, the SB may be programmable to allocate a portion of time for metadata communication in sync mode and another portion for regular administrative control and maintenance in non-sync mode. Metadata may be transferred over the SB in sync mode during some allocated periods. The metadata may be redundant data (e.g., duplicated from the MB), parity/ECC data (e.g., providing periodical parity check for the MB data), or additional MB data.

As described with respect to FIG. 2, the MB interface may have a greater number of data lanes than the SB interface. Thus, the SB lane may be mapped to every main band lane in a round-robin fashion to check the data integrity of the main band periodically. For example, as shown in diagram 450 of FIG. 4, a first internal MB data may be provided to the generator 406 for duplication and/or parity/ECC data generation, followed by a second internal MB data, and so on.

In some aspects, internal MB data (labeled “MB Data Int”) may also be provided to the generator 404. The generator 404 may be configured to provide the internal MB data (or a processed version thereof) for communication via the SB clock lane (e.g., instead of an SB or MB clock), further increasing throughput or reliability. For example, similar to the techniques described with respect to generator 406, internal MB data may be processed to generate parity/ECC data for communication via the SB clock lane, or the MB data may be communicated via the SB clock lane for redundancy, to increase reliability. The internal MB data may be data in addition to any data sent via the MB interface to increase throughput. As shown in diagram 451 of FIG. 4, the SB clock lane may be mapped to every main band lane in a round-robin fashion to check the data integrity of the main band periodically.

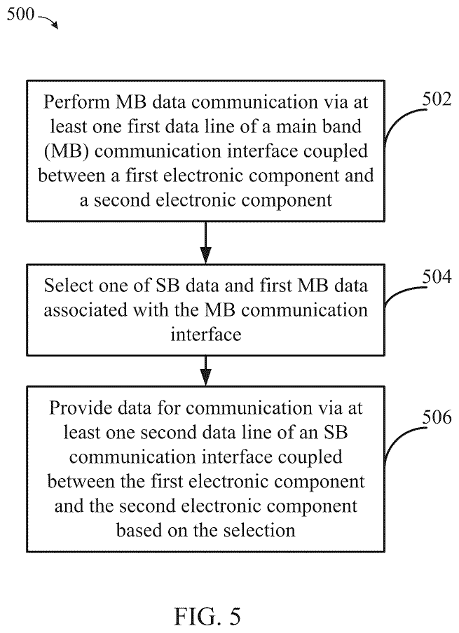

FIG. 5 illustrates example operations 500 for data communication, in accordance with certain of the present disclosure. The operations 500 may be performed, for example, by communication circuitry, such as the communication circuitry 202 including the SB circuitry 400.

At block 502, the communication circuitry performs MB data communication via at least one first data line of an MB communication interface (e.g., MB interface 230 of FIG. 2) coupled between a first electronic component (e.g., Chiplet-1 shown in FIG. 2) and a second electronic component (e.g., Chiplet-2 shown in FIG. 2).

At block 504, the communication circuitry may select one of SB data (e.g., such as the internal SB data labeled “SB Data Int” in FIG. 4, which may be control information in accordance with regular UCIe operations) and first MB data (e.g., ECC/parity data or redundant MB data) associated with the MB communication interface. The SB data may include control information associated with the MB data communication via the at least one first data line.

At block 506, the communication circuitry may provide data for communication via at least one second data line of an SB communication interface (e.g., SB interface 232) coupled between the first electronic component and the second electronic component based on the selection. In other words, the communication circuitry may select between communicating regular SB data (e.g., SB Data Int) such as control information per regular UCIe protocols or communicating ECC/parity data or redundant MB data which may be generated based on MB data (e.g., internal MB data labeled “MB Data Int” in FIG. 4).

The communication circuitry may select one of an SB clock signal and a first MB clock signal. The communication circuitry may provide the one of the SB clock signal and the first MB clock signal for communication from the first electronic component to the second electronic component via a first clock line of the SB communication interface. In some aspects, the communication circuitry may communicate a second MB clock signal from the first electronic component to the second electronic component via a second clock line of the MB communication interface. The first MB clock signal may be synchronized with the second MB clock signal. The communication circuitry may generate, via a frequency divider circuit (e.g., divider circuit 402 of FIG. 4), the first MB clock signal based on the second MB clock signal. The first MB clock signal may be a frequency-divided version of the second MB clock signal. In some aspects, the communication circuitry may provide second MB data for communication via the first clock line of the SB communication interface.

In some aspects, the communication circuitry may generate the data for communication via the at least one second data line based on the first MB data. For example, the data for communication via the at least one second data line may include parity information associated with the first MB data.

In some aspects, the communication circuitry may communicate the first MB data from the first electronic component to the second electronic component. Providing the data for communication via the at least one second data line may include providing the first MB data to the at least one second data line for communication from the first electronic component to the second electronic component.

In some aspects, the communication circuitry communicates second MB data from the first electronic component to the second electronic component, the second MB data being different than the first MB data. The first MB data may be one of a plurality of MB data. Providing the data may include selecting, as the data to be communicated, each of the plurality of MB data during a respective one of different time periods.

### Example Aspects

Aspect 1: An apparatus for data communication, comprising: a main band (MB) communication interface comprising at least one first data line coupled between a first electronic component and a second electronic component and configured to perform MB data communication via the at least one first data line; a side band (SB) communication interface comprising at least one second data line coupled between the first electronic component and the second electronic component; and a first processing component configured to provide data for communication via the at least one second data line of the SB communication interface, wherein to provide the data, the first processing component is configured to select one of SB data and first MB data associated with the MB communication interface.
Aspect 2: The apparatus of Aspect 1, wherein the SB data comprises control information associated with the MB data communication via the at least one first data line.
Aspect 3: The apparatus of Aspect 1 or 2, wherein: the SB communication interface further comprises a first clock line; and the apparatus further comprising a second processing component configured to select one of an SB clock signal and a first MB clock signal for communication via the first clock line of the SB communication interface.
Aspect 4: The apparatus of Aspect 3, wherein: the MB communication interface further comprises a second clock line configured to communicate a second MB clock signal from the first electronic component to the second electronic component; and the first MB clock signal is synchronized with the second MB clock signal.
Aspect 5: The apparatus of Aspect 4, further comprising a frequency divider circuit configured to generate the first MB clock signal based on the second MB clock signal.
Aspect 6: The apparatus of Aspect 4 or 5, wherein the first MB clock signal is a frequency-divided version of the second MB clock signal.
Aspect 7: The apparatus according to any of Aspects 3-6, wherein the second processing component is further configured to provide second MB data associated with the MB communication interface for communication via the first clock line of the SB communication interface.
Aspect 8: The apparatus according to any of Aspects 1-7, wherein the first processing component is configured to generate the data for communication via the at least one second data line based on the first MB data.
Aspect 9: The apparatus of Aspect 8, wherein the data for communication via the at least one second data line comprises parity information associated with the first MB data.
Aspect 10: The apparatus according to any of Aspects 1-9, wherein: the MB communication interface is configured to communicate the first MB data from the first electronic component to the second electronic component; and to provide the data for communication via the at least one second data line, the first processing component is configured to provide the first MB data to the at least one second data line for communication from the first electronic component to the second electronic component.
Aspect 11: The apparatus according to any of Aspects 1-10, wherein the MB communication interface is configured to communicate second MB data from the first electronic component to the second electronic component, the second MB data being different than the first MB data.
Aspect 12: The apparatus according to any of Aspects 1-11, wherein: the first MB data is one of a plurality of MB data; and to provide the data, the first processing component is configured to select, as the data to be communicated, each of the plurality of MB data during a respective one of different time periods.
Aspect 13: A method for data communication, comprising: performing main band (MB) data communication via at least one first data line of an MB communication interface coupled between a first electronic component and a second electronic component; selecting one of side band (SB) data and first MB data associated with the MB communication interface; and providing data for communication via at least one second data line of an SB communication interface coupled between the first electronic component and the second electronic component based on the selection.
Aspect 14: The method of Aspect 13, wherein the SB data comprises control information associated with the MB data communication via the at least one first data line.
Aspect 15: The method of Aspect 13 or 14, further comprising: selecting one of an SB clock signal and a first MB clock signal; and providing the one of the SB clock signal and the first MB clock signal for communication from the first electronic component to the second electronic component via a first clock line of the SB communication interface.
Aspect 16: The method of Aspect 15, further comprising communicating a second MB clock signal from the first electronic component to the second electronic component via a second clock line of the MB communication interface, the first MB clock signal being synchronized with the second MB clock signal.
Aspect 17: The method of Aspect 16, further comprising generating, via a frequency divider circuit, the first MB clock signal based on the second MB clock signal.
Aspect 18: The method of Aspect 16 or 17, wherein the first MB clock signal is a frequency-divided version of the second MB clock signal.
Aspect 19: The method according to any of Aspects 15-18, further comprising providing second MB data for communication via the first clock line of the SB communication interface.
Aspect 20: The method according to any of Aspects 13-19, further comprising generating the data for communication via the at least one second data line based on the first MB data.
Aspect 21: The method of Aspect 20, wherein the data for communication via the at least one second data line comprises parity information associated with the first MB data.
Aspect 22: The method according to any of Aspects 13-21, wherein: the method further comprises communicating the first MB data from the first electronic component to the second electronic component; and providing the data for communication via the at least one second data line comprises providing the first MB data to the at least one second data line for communication from the first electronic component to the second electronic component.
Aspect 23: The method according to any of Aspects 13-22, further comprising communicating second MB data from the first electronic component to the second electronic component, the second MB data being different than the first MB data.
Aspect 24: The method according to any of Aspects 13-23, wherein: the first MB data is one of a plurality of MB data; and providing the data comprises selecting, as the data to be communicated, each of the plurality of MB data during a respective one of different time periods.
Aspect 25: A multi-chiplet package, comprising: a first chiplet; a second chiplet; a main band (MB) communication interface comprising at least one first data line coupled between the first chiplet and the second chiplet and configured to perform MB data communication via the at least one first data line; a side band (SB) communication interface comprising at least one second data line coupled between the first chiplet and the second chiplet; and a processing component configured to provide data for communication via the at least one second data line of the SB communication interface, wherein to provide the data, the processing component is configured to select one of SB data and MB data associated with the MB communication interface.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining”may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation, and details of the methods and apparatus described above without departing from the scope of the claims.

What is claimed is:

1. An apparatus for data communication, comprising:
a main band (MB) communication interface comprising at least one first data line coupled between a first electronic component and a second electronic component and configured to perform MB data communication via the at least one first data line;
a side band (SB) communication interface comprising at least one second data line coupled between the first electronic component and the second electronic component; and
a first processing component configured to provide data for communication via the at least one second data line of the SB communication interface, wherein to provide the data, the first processing component is configured to select one of SB data and first MB data associated with the MB communication interface.

2. The apparatus of claim 1, wherein the SB data comprises control information associated with the MB data communication via the at least one first data line.

3. The apparatus of claim 1, wherein:
the SB communication interface further comprises a first clock line; and
the apparatus further comprising a second processing component configured to select one of an SB clock signal and a first MB clock signal for communication via the first clock line of the SB communication interface.

4. The apparatus of claim 3, wherein:
the MB communication interface further comprises a second clock line configured to communicate a second MB clock signal from the first electronic component to the second electronic component; and
the first MB clock signal is synchronized with the second MB clock signal.

5. The apparatus of claim 4, further comprising a frequency divider circuit configured to generate the first MB clock signal based on the second MB clock signal.

6. The apparatus of claim 4, wherein the first MB clock signal is a frequency-divided version of the second MB clock signal.

7. The apparatus of claim 3, wherein the second processing component is further configured to provide second MB data associated with the MB communication interface for communication via the first clock line of the SB communication interface.

8. The apparatus of claim 1, wherein the first processing component is configured to generate the data for communication via the at least one second data line based on the first MB data.

9. The apparatus of claim 8, wherein the data for communication via the at least one second data line comprises parity information associated with the first MB data.

10. The apparatus of claim 1, wherein:
the MB communication interface is configured to communicate the first MB data from the first electronic component to the second electronic component; and
to provide the data for communication via the at least one second data line, the first processing component is configured to provide the first MB data to the at least one second data line for communication from the first electronic component to the second electronic component.

11. The apparatus of claim 1, wherein the MB communication interface is configured to communicate second MB data from the first electronic component to the second electronic component, the second MB data being different than the first MB data.

12. The apparatus of claim 1, wherein:
the first MB data is one of a plurality of MB data; and
to provide the data, the first processing component is configured to select, as the data to be communicated, each of the plurality of MB data during a respective one of different time periods.

13. A method for data communication, comprising:
performing main band (MB) data communication via at least one first data line of an MB communication interface coupled between a first electronic component and a second electronic component;
selecting one of side band (SB) data and first MB data associated with the MB communication interface; and
providing data for communication via at least one second data line of an SB communication interface coupled between the first electronic component and the second electronic component based on the selection.

14. The method of claim 13, wherein the SB data comprises control information associated with the MB data communication via the at least one first data line.

15. The method of claim 13, further comprising:
selecting one of an SB clock signal and a first MB clock signal; and
providing the one of the SB clock signal and the first MB clock signal for communication from the first electronic component to the second electronic component via a first clock line of the SB communication interface.

16. The method of claim 15, further comprising communicating a second MB clock signal from the first electronic component to the second electronic component via a second clock line of the MB communication interface, the first MB clock signal being synchronized with the second MB clock signal.

17. The method of claim 16, further comprising generating, via a frequency divider circuit, the first MB clock signal based on the second MB clock signal.

18. The method of claim 16, wherein the first MB clock signal is a frequency-divided version of the second MB clock signal.

19. The method of claim 15, further comprising providing second MB data for communication via the first clock line of the SB communication interface.

20. The method of claim 13, further comprising generating the data for communication via the at least one second data line based on the first MB data.

21. The method of claim 20, wherein the data for communication via the at least one second data line comprises parity information associated with the first MB data.

22. The method of claim 13, wherein:
the method further comprises communicating the first MB data from the first electronic component to the second electronic component; and
providing the data for communication via the at least one second data line comprises providing the first MB data to the at least one second data line for communication from the first electronic component to the second electronic component.

23. The method of claim 13, further comprising communicating second MB data from the first electronic component to the second electronic component, the second MB data being different than the first MB data.

24. The method of claim 13, wherein:
the first MB data is one of a plurality of MB data; and
providing the data comprises selecting, as the data to be communicated, each of the plurality of MB data during a respective one of different time periods.

25. A multi-chiplet package, comprising:
a first chiplet;
a second chiplet;
a main band (MB) communication interface comprising at least one first data line coupled between the first chiplet and the second chiplet and configured to perform MB data communication via the at least one first data line;
a side band (SB) communication interface comprising at least one second data line coupled between the first chiplet and the second chiplet; and
a processing component configured to provide data for communication via the at least one second data line of the SB communication interface, wherein to provide the data, the processing component is configured to select one of SB data and MB data associated with the MB communication interface.
